(19) United States
(12) Patent Application Publication
(10) Pub. No.: US 2017/0127538 A1
(43) Pub. Date: May 4, 2017

(54) FASTENING SYSTEM FOR LIGHT EMITTING DISPLAY MODULES

(71) Applicant: Steven James Westhoff, Brookings, SD (US)

(72) Inventor: Steven James Westhoff, Brookings, SD (US)

(21) Appl. No.: 14/929,868

(22) Filed: Nov. 2, 2015

(51) Int. Cl. H05K 5/00

(52) U.S. Cl. CPC H05K 5/0021; H05K 5/0017

(57) ABSTRACT

A fastening system for connecting display modules can include a corner block, a retainer, and a fastener. The corner block can include a first block plate and a second block plate, the first and second block plates being angled relative to one another, the corner block including a block fastener hole through the first block plate. The retainer can include a first retainer plate and a second retainer plate, the first and second retainer plates being angled relative to one another, the retainer including a retainer fastener hole through the first retainer plate, wherein interior surfaces of the first and second block plates are proximate to respective exterior surfaces of the first and second retainer plates and the corner block and the retainer are aligned such that the retainer fastener hole is substantially aligned with the block fastener hole. The fastener can be retained by at least one of the corner block and the retainer proximate to or in at least one of the block fastener hole and the retainer fastener hole, the fastener being movable between an unengaged position and an engaged position, so that a portion of the fastener extends through the block fastener hole and the retainer fastener hole when the fastener is in the engaged position.

### BACKGROUND

Displays comprising a plurality of light-emitting elements, or display modules, are used for the display of information. In some applications, such as digital billboards or scoreboards, individual display modules can be connected together and operated collectively to form a larger display surface. Fastening hardware have been used to connect individual display modules to form larger display surfaces.

### SUMMARY

A fastening system for connecting display modules can include a corner block and a retainer with one or more corresponding holes for receiving one or more fasteners. The one or more fasteners can be movable between an engaged position that secures the fastening system to a mating structure and an unengaged position that allows the fastening system to be disengaged from the mating structure. The fastening system can be used to mount a first display module to a second display module as part of a larger display system.

The present disclosure describes a fastening system including a corner block, a retainer, and a fastener. The corner block can include a first block plate and a second block plate, the first and second block plates being angled relative to one another, the corner block including a block fastener hole through the first block plate. The retainer can include a first retainer plate and a second retainer plate, the first and second retainer plates being angled relative to one another, the retainer including a retainer fastener hole through the first retainer plate, wherein interior surfaces of the first and second block plates are proximate to respective exterior surfaces of the first and second retainer plates and the corner block and the retainer is aligned such that the retainer fastener hole is substantially aligned with the block fastener hole. The fastener can be retained by at least one of the corner block and the retainer proximate to or in at least one of the block fastener hole and the retainer fastener hole, the fastener being movable between an unengaged position and an engaged position, so that a portion of the fastener extends through the block fastener hole and the retainer fastener hole when the fastener is in the engaged position.

The present disclosure also describes a method comprising providing or receiving a first display module including a first fastening system coupled thereto. The first fastening system comprises a first corner block including a first block plate and a second block plate, the first and second block plates being angled relative to one another, the first corner block comprising a first block fastener hole through the first block plate, a first retainer comprising a first retainer plate and a second retainer plate, the first and second retainer plates being angled relative to one another, the first retainer comprising a first retainer fastener hole through the first retainer plate, wherein interior surfaces of the first and second block plates are configured to be proximate to or in substantially intimate contact with respective exterior surfaces of the first and second retainer plate such that the first retainer fastener hole is substantially aligned with the first block fastener hole, and a first fastener retained by at least one of the first corner block and the first retainer proximate to or in at least one of the second block fastener hole and the second retainer fastener hole, the first fastener being movable relative to the first retainer between a first unengaged position and a first engaged position. The method further includes positioning the first display module so that the first fastening system is adjacent to a corresponding first mating structure, and moving the first fastener to the first engaged position so that a portion of the first fastener extends through the first retainer fastener hole and the first block fastener hole to engage the corresponding first mating structure. In an example, the corresponding first mating structure is on a second display module, such as on a second fastening system of the second display module. Positioning the first display module can comprise positioning the first fastening system adjacent to the second fastening system and engaging the first fastening system with the first mating structure on the second fastening system.

This summary is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A is an isometric view of an example display module for the display of visual information.

FIG. 1B is an isometric view of an example fastening system for use in the display module of FIG. 1A.

FIG. 2A is an isometric view of an interior of an example corner block that can be used in the example fastening system of FIG. 1B.

FIG. 2B is a cross-sectional view of the corner block of FIG. 2A.

FIG. 2C is an isometric view of an exterior surface of the corner block of FIG. 2A.

FIG. 3A is an isometric view of an example retainer that can be used in the fastening system of FIG. 1B.

FIG. 3B is a cross-sectional view of the retainer of FIG. 3A.

FIG. 4 is a side view of an example fastener that can be used in the example fastening system of FIG. 1B.

FIG. 5 shows an exploded perspective view of the fastening system of FIG. 1B.

FIG. 6A is an isometric view of an example fastening system adjacent to a corresponding mating structure on a rigging beam.

FIG. 6B is a detailed isometric view of an example fastening system adjacent to a corresponding mating structure on a rigging beam.

FIG. 6C shows a side view of the example fastening system adjacent to the rigging beam.

FIG. 6D shows an end view of the example fastening system adjacent to the rigging beam.

FIG. 7A is an isometric view of a frame of a first example display module including a first example fastening system, wherein the first display module is positioned adjacent to a frame of a second example display module having a second example fastening system that includes a corresponding mating structure.

FIG. 7B is a close-up front view of the first and second fastening systems of the first and second display modules of FIG. 7A.

FIG. 7C is an isometric view of a first example corner block and a second example corner block used in the first and second fastening systems of the first and second displays of FIGS. 7A and 7B.

FIG. 8 is a flow diagram of an example method of connecting one or more display modules.

FIG. 9 is a front view of example first and second fastening systems connected to form a joint between first and second display modules.

FIG. 10 is a front view of four example fastening systems connected to form multiple joints between four display modules.

### DETAILED DESCRIPTION

In the following Detailed Description, reference is made to the accompanying drawing which form a part hereof. The drawings show, by way of illustration, examples of fastening systems and methods for the connection of one or more display modules to mating structures, such as rigging beams or other display modules. The examples are described in sufficient detail to enable those skilled in the art to practice, and it is to be understood that other embodiments can be utilized and that changes can be made without departing from the scope of the present disclosure. Therefore, the following Detailed Description is not to be taken in a limiting sense, and the scope of the present disclosure is defined by the appended claims and their equivalents.

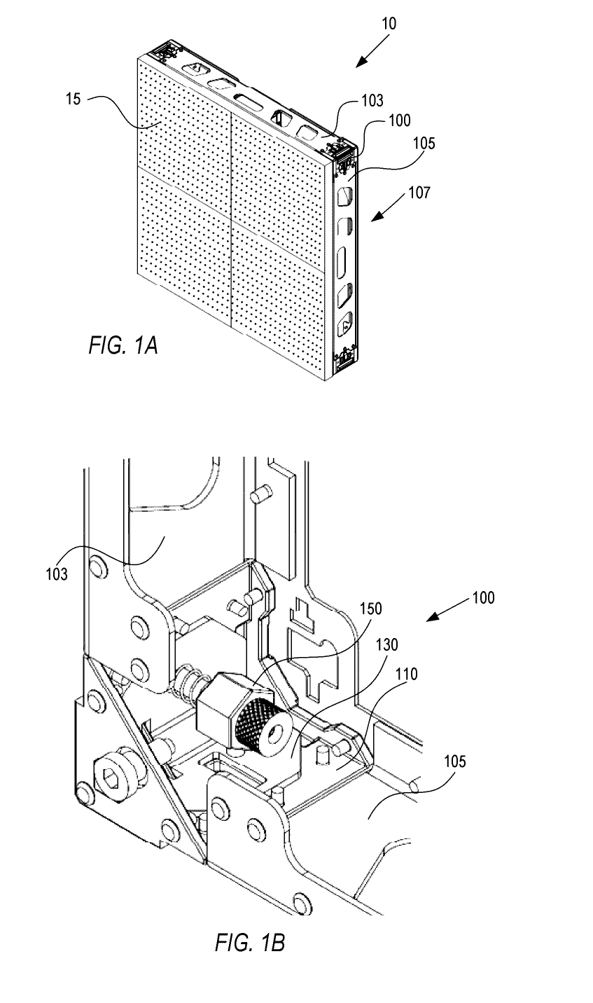

FIG. 1A shows an example of a display module 10. The display module 10 can comprise one or more light-emitting elements 15 connected to a frame 107. The light-emitting elements 15 can comprise any light-emitting element such as light-emitting diodes (LEDs). For the sake of brevity, the light-emitting elements 15 will be referred to as LEDs 15 throughout the present disclosure. However, it will be understood that light-emitting devices other than LEDs can be used, however, including, but not limited to, light-emitting diodes (LEDs), organic light-emitting diodes (OLEDs), organic light-emitting transistors (OLETs), surface-conduction electron-emitter display devices (SEDs), field-emission display devices (FEDs), laser TV quantum dot liquid crystal display devices, quantum dot display devices (QD-LED), ferro-liquid display devices (FLDs), liquid crystal display devices (LCDs), and thick-film dielectric electroluminescent devices (TDELs). A plurality of LEDs 15 can be arranged into pixels. For example, a red LED 15, a green LED 15, and a blue LED 15 can be arranged in proximity to each other to form a pixel, wherein the individual red, green, and blue LEDs 15 of the pixel can be controlled so that the pixel can display essentially any visible color.

The frame 107 can include a plurality of panel sides, such as panel sides 103, 105. The display module 10 also includes at least one fastening system 100, which can be part of the frame 107 or can be a separate component from the frame 107. As described in more detail below, the fastening system 100 can couple the display module 10 to a corresponding mating structure, such as on another adjacent display module or on a mounting structure, such as a rigging beam.

FIG. 1B shows an example of a fastening system 100 that can be used in the display module 10. The fastening system 100 can be used to couple two panel sides 103, 105 such as to form at least part of the frame 107. The fastening system 100 can be used for connecting one or more adjacent display modules 10. The display modules 10 can have an internal pixel spacing, e.g., the spacing between adjacent pixels of the LEDs 15 within the same display module. The fastening system 100 can be configured so that a pixel spacing between connected display modules 10, e.g., the spacing between the outermost pixels of a first display module 10 and the corresponding outermost pixels of a second display module 10 that are to be adjacent to the outermost pixels of the first display module 10, maintains substantially the same spacing as the internal pixel spacing of the display modules 10. In an example, maintaining pixel spacing can include maintaining a uniform pixel spacing between one or more display modules connected to form a larger display surface.

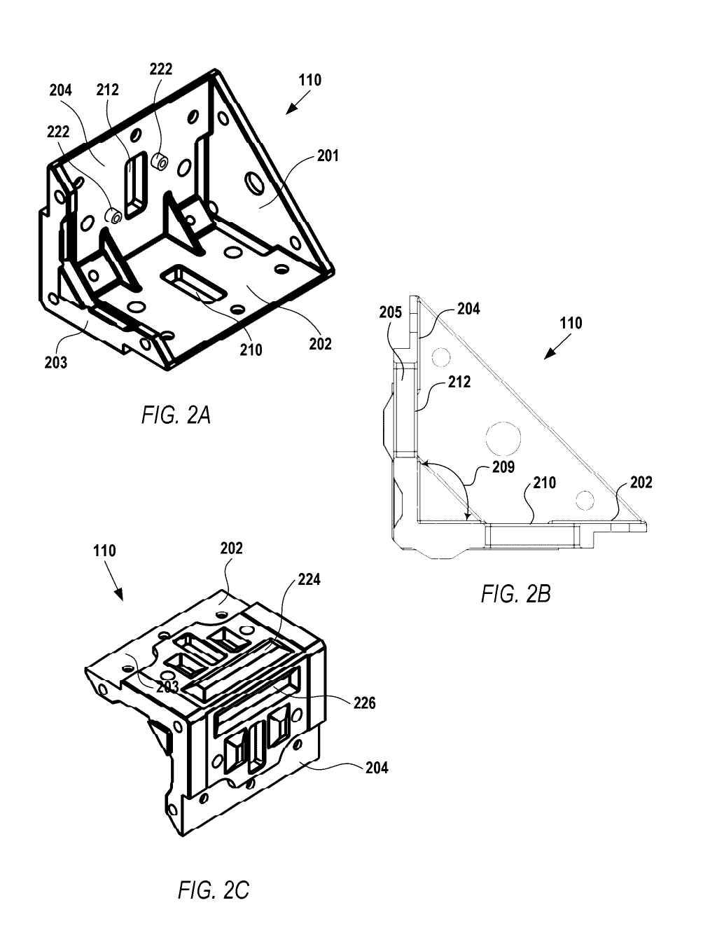

In an example, the fastening system 100 can include a corner block 110, a retainer 130, and a fastener 150. FIGS. 2A-2C show various views of an example corner block 110. The corner block 110 can include a first block plate 202 and a second block plate 204. The first block plate 202 can be angled relative to the second block plate 204. The corner block 110 can include a gusset plate 201 that can attach to at least one of the first block plate 202 and the second block plate 204.

The gusset plate 201 can maintain a specified angle between the first block plate 202 and the second block plate 204.

The corner block 110 can include a block fastener hole 210 that can extend through the first block plate 202. The corner block 110 can include a block receiver hole 212 that can extend through the second block plate 204. The block fastener hole 210 and the block receiver hole 212 can include any shape without altering the effect of the block fastener hole 210 or the block receiver hole 212. Shapes of the holes 210, 212 can include, but are not limited to, a square, a triangle, an oval, a bilaterally symmetric shape, and a non-bilaterally symmetric shape. In an example, the block fastener hole 210 can have a generally rectangular shape. In an example, the block receiver hole 212 can have a generally rectangular shape. In an example, the block receiver hole 212 can include a substantially circular shape, such as a threaded hole.

The corner block 110 can include a pocket plate 203 that can attach to at least one of the first block plate 202 and the second block plate 204. The pocket plate 203 can define a gap 205 between the pocket plate 203 and at least one of the first block plate 202 and the second block plate 204. The gap 205 can be used to locate one or more components, such as one of the side panels 103, 105, with respect to at least one of the first block plate 202 and the second block plate 204. The first and second block plates 202, 204 can include at least a portion of the pocket plate 203, such as an exterior surface of the first and second block plates 202, 204 including at least a portion of an exterior surface of the pocket plate 203.

A specified corner block angle 209 can be formed between the first block plate 202 and the second block plate 204 of the corner block 110. The corner block angle 209 can be selected to be any value from approximately 0 degrees to approximately 180 degrees, including, but not limited to, 1 degree, 2 degrees, 3 degrees, 5 degrees, 10 degrees, 15 degrees, 20 degrees, 25 degrees, 30 degrees, 35 degrees, 40 degrees, 45 degrees, 50 degrees, 55 degrees, 60 degrees, 65 degrees, 70 degrees, 75 degrees, 80 degrees, 85 degrees, 90 degrees, 95, 100 degrees, 105 degrees, 110 degrees, 115 degrees, 120 degrees, 125 degrees, 130 degrees, 135 degrees, 140 degrees, 145 degrees, 150 degrees, 155 degrees, 160 degrees, 165 degrees, 170 degrees, 175 degrees, 177 degrees, 178 degrees, 179 degrees, or other number of degrees. For example, FIG. 2B shows an example corner block 110 where the corner block angle 209 between the first block plate 202 and the second block plate 204 is approximately 90 degrees. Display modules of other non-rectangular shapes, such as pentagons and hexagons or of non-regular shapes, can include corner block angles 209 greater than or less than 90 degrees. Non-rectangular display modules can be used to form, for example, irregular or non-rectangular display surfaces, such as a display suggesting a soccer ball or a honeycomb pattern.

The corner block 110 can include at least one block fastener stop 222 that can extend from an interior surface of the second block plate 204. The block fastener stop 222 can be located proximate to the block receiver hole 212. The block fastener stop 222 can be a structure capable of interfering with the rotational motion of a fastener 150 that extends through the block receiver hole 212 (described in more detail below). An example of a structure that the fastener stop 222 can take includes, but is not limited to, a protrusion, such as a bump, a knob, a hump, or a ridge. As used herein, the term “proximate to,” when referring to the block fastener stop 222 and the block receiver hole 212, can include a distance that is approximately one-half the length of the largest dimension of the block receiver hole 212. For example, where the block receiver hole 212 has a rectangular shape, the block fastener stop 222 can be spaced from the block receiver hole by no more than a distance of approximately one-half the length of the longest side of the block receiver hole 212.

Exterior surfaces of at least one of the first block plate 202 and the second block plate 204 of the corner block 110, best seen in FIG. 2C, can include at least one of a protuberance 224 extending from the exterior surface and a cavity 226 projecting into the exterior surface. In an example, at least one of a corresponding cavity and a corresponding protuberance can be included on another structure, such as a corresponding mating structure, that can be engaged by the at least one of protuberance 224 and the cavity 226. For example, a protuberance 224 on the fastening system 100 can engage with a corresponding cavity on the corresponding mating structure. Similarly, if the fastening system 100 includes a cavity 226, it can engage with a corresponding protuberance on the corresponding mating structure. The engagement between the protuberance 224 and the corresponding cavity, or between the cavity 226 and the corresponding protuberance, or both, can locate the fastening system 100 with respect to the corresponding mating structure, as described in more detail below. Examples of the corresponding mating structure include, but are not limited to, a rigging beam, a horizontal stiffener, or a second corner block in a second display module.

The protuberance 224 or the cavity 226 can include any volumetric shape without altering the effect of the protuberance 224 or the cavity 226. Examples include, but are not limited to, a cube or a sector thereof, a pyramid or a sector thereof, a sector of a sphere, a bilaterally symmetric shape, or a non-bilaterally symmetric shape. In the example shown in FIG. 2C, the volumetric shape of the protuberance 224 and the cavity 226 can include a frustum.

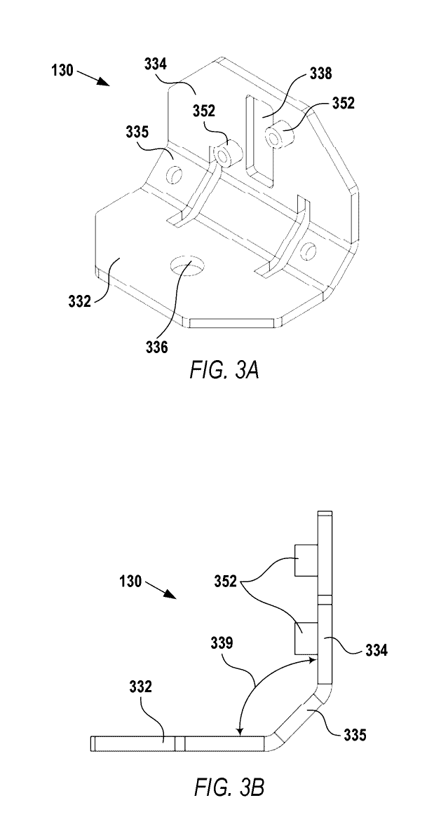

FIGS. 3A and 3B shows various views of an example retainer 130. The retainer 130 can include a first retainer plate 332 and a second retainer plate 334. The retainer 130 can include a middle retainer plate 335 between the first and second retainer plates 332, 334. The middle retainer plate 335 can provide for a specified angle between the first retainer plate 332 and the second retainer plate 334. The retainer 130 can include a retainer fastener hole 336 that can extend through the first retainer plate 332. The retainer 130 can include a retainer receiver hole 338 that can extend through the second receiver plate 334. The retainer fastener hole 336 and the retainer receiver hole 338 can include any shape without altering the effect of the retainer fastener hole 336 or the retainer receiver hole 338. Shapes of the holes 336, 338 can include, but are not limited to, a square, a triangle, an oval, a bilaterally symmetric shape, and a non-bilaterally symmetric shape. In an example, the retainer fastener and retainer receiver holes 336, 338 can include a substantially rectangular shape. In an example, the retainer fastener hole 336 can include a substantially circular shape.

A retainer angle 339, best seen in FIG. 3B, can be formed between the first retainer plate 336 and the second retainer plate 338. The retainer angle 339 can be selected to be any value from approximately 0 degrees to approximately 180 degrees, including, but not limited to, 1 degree, 2 degrees, 3 degrees, 5 degrees, 10 degrees, 15 degrees, 20 degrees, 25 degrees, 30 degrees, 35 degrees, 40 degrees, 45 degrees, 50 degrees, 55 degrees, 60 degrees, 65 degrees, 70 degrees, 75 degrees, 80 degrees, 85 degrees, 90 degrees, 95, 100 degrees, 105 degrees, 110 degrees, 115 degrees, 120 degrees, 125 degrees, 130 degrees, 135 degrees, 140 degrees, 145 degrees, 150 degrees, 155 degrees, 160 degrees, 165 degrees, 170 degrees, 175 degrees, 177 degrees, 178 degrees, 179 degrees, or other number of degrees. For example, FIG. 3B shows an example retainer 130 where the retainer angle 339 between the first retainer plate 336 and the second retainer plate 338 is approximately 90 degrees.

The retainer 130 can include at least one retainer fastener stop 352 that can extend from an interior surface of the retainer 130. The retainer fastener stop 352 can be located proximate to the retainer receiver hole 338. The retainer fastener stop 352 can be any structure capable of interfering with the rotational motion of a fastener that extends through the retainer receiver hole 338. An example of the structure of the retainer fastener stop includes, but is not limited to, a protrusion, such as a bump, a knob, a hump, or a ridge. As used herein, “proximate to,” when referring to the retainer fastener stop 352 and the retainer receiver hole 338, can include a distance that is no more than approximately one-half the length of the largest dimension of the retainer receiver hole 338. For example, if the retainer receiver hole 338 has a rectangular shape, the retainer fastener stop 352 can be spaced from the retainer receiver hole 338 by a distance of no more than approximately one-half the length of the longest side of the rectangular retainer receiver hole 338.

As shown in FIG. 1B, the fastening system 100 can include a fastener 150. The fastener 150 can include any structure or combination of structures that can join two surfaces together as a joint, such as to create an engaged position. The fastener 150 can include any component that can connect a first body to a second body, such as a rivet, a screw, bolt, or threaded rod in combination with a threaded hole, a threaded bolt or a threaded rod in combination with a nut, a toggle bolt, or an expansion bolt, such as a wedge or anchor bolt. The fastener 150 can be located within the retainer fastener hole 336 and movable relative to the retainer 130, such as between a retracted or unengaged position and an extended or engaged position.

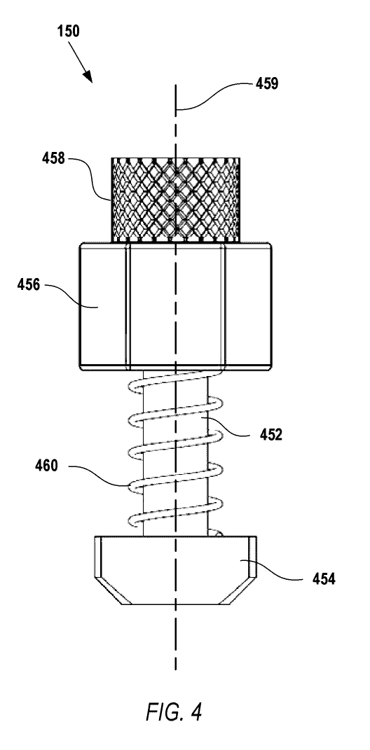

In an example, best shown in FIG. 4, the fastener 150 comprises a T-bolt fastener 150. The T-bolt fastener 150 can include a shaft 452 defining a longitudinal axis 459. The T-bolt fastener 150 can include a flange 454. The T-bolt fastener 150 can include a nut 456. The T-bolt fastener 150 can include a turn handle 458. In an example, the T-bolt fastener 150 can include a biasing structure, such as a retaining spring 460. All or a portion of the shaft 452 can be threaded. The flange 454 can include any shape without altering the effect of the flange 454, including, but not limited to, a square, a triangle, an oval, a bilaterally symmetric shape, or a non-bilaterally symmetric shape. The shape of the flange 454 in a plane parallel to or perpendicular to the longitudinal axis 459 can include a substantially rectangular shape. The nut 456 can be threaded onto a portion of the shaft 452 that is threaded. The turn handle 458 can be attached to the T-bolt fastener 150, such as by threading the turn handle 458 onto the shaft 452 or by securing the turn handle 458 to the shaft 452 with a set screw.

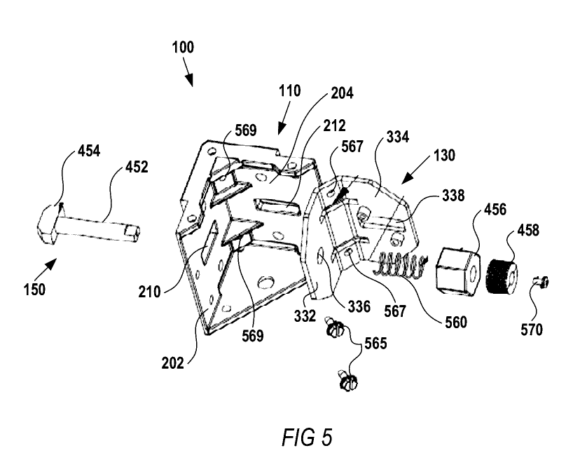

FIG. 5 shows an exploded view of the example fastening system 100. The retainer 130 can be located proximate to the corner block 110, such as in contact with the corner block 110. In an example, at least a portion of the interior surfaces of the first and second block plates 202, 204 can contact at least a portion of the exterior surfaces of the first and second retainer plates 332, 334.

The block fastener hole 210 can be substantially aligned with the retainer fastener hole 336. Alignment of the fastener holes 210 and 336 can locate the first and second block plates 202, 204 in a specified position with respect to the first and second retainer plates 332, 334. In an example, the retainer fastener hole 336 can be substantially circular in shape and the block fastener hole 210 can be substantially rectangular in shape. In such an example, the centroid of the circular retainer fastener hole 336 can substantially align with the centroid of the rectangular block fastener hole 210.

The block receiver hole 212 can be substantially aligned with the retainer receiver hole 338. Alignment of the receiver holes 212 and 338 can allow the holes 212 and 338 to be capable of receiving the fastener 150. In an example, the block and retainer receiver holes 212, 338 can be substantially rectangular in shape. The centroid of the rectangular block receiver hole 212 can substantially align with the centroid of the rectangular retainer receiver hole 338. The block receiver hole 212 can be of approximately the same size and shape as the retainer receiver hole 338. For example, a perimeter of the block receiver hole 212 can substantially align with a perimeter of the retainer receiver hole 338.

Interior surfaces of the first and second block plates 202, 204 can be proximate to the respective exterior surfaces of the first and second retainer plates 332, 334. For example, the first and second block plates 202, 204 can be configured to receive and be in substantially intimate contact with respective exterior surfaces of the first and second retainer plates 332, 334. The retainer fastener hole 336 can be substantially aligned with the block fastener hole 210. In an example, a portion of the fastener 150 can extend into the block fastener hole 210 when the fastener 150 is in the engaged position. The same portion of the fastener 150 can be outside of the block fastener hole 210 when the fastener 150 is in the unengaged position.

The retainer 130 can be secured to the corner block 110. For example, the retainer 130 can be coupled to the corner block 110 with at least one connector, such as a rivet, or a screw and a threaded hole. As shown in the example of FIG. 5, at least one screw 565 can extend through a clearance hole 567 in the retainer 130 so that the screw 565 can engage a threaded hole 569 located in the corner block 110. The screw 565 can couple the retainer 130 to the corner block 110. The clearance hole 567 can include any opening large enough to allow an object, such as the screw 565, to pass through the clearance hole 567 without contacting the sides of the clearance hole 567. In an example, the retainer 130 can be welded to the corner block 110.

The fastener 150 can be controllably restrained, or retained, in an unengaged position relative to the fastening system 100, such as by maintaining a desired location with respect to the corner block 110 or the retainer 130, or both. In an example where the fastener 150 is a T-bolt fastener 450 with the nut 456, the fastener 150 can be located in the retainer fastener hole 336 and can include a biasing structure such as the retaining spring 460. The biasing structure can exert force on the fastener 150 so as to locate the fastener 150 in the unengaged position relative to the retainer 130. For example, if the biasing structure is a spring 460, then the spring 460 can be located around the shaft 452 between the nut 456 and the retainer 130 such that the retaining spring 460 exerts a force to bias the flange 454 of the T-bolt fastener 450 toward the exterior surface of the retainer 130. The biasing force of the spring 460 can locate the T-bolt fastener 450 relative to the retainer 130.

The T-bolt fastener 450 can be retained relative to the retainer 130 by controlling the size of at least one of the block fastener hole 210 and the retainer fastener hole 336. For example, where the T-bolt fastener 450 is located in the retainer fastener hole 336, the difference between the diameter of the shaft 452 and the diameter of the fastener hole 336 can be made small so that misalignment between the longitudinal axis 459 of the T-bolt fastener 450 and an axis perpendicular to the retainer fastener hole 336 will prevent or impede motion of the T-bolt fastener 450 with respect to the plate fastener hole 336. This can locate the

T-bolt fastener 450 in a retained position.

The T-bolt fastener 450 can include a turn handle 458. The turn handle 458 can attach to the T-bolt fastener 450 to provide a grasping surface. The turn handle 458 can allow a user can twist the T-bolt fastener 450 about the longitudinal axis 459, which can move the T-bolt fastener 450 between an unengaged position and an engaged position. The turn handle 458 can attach to the T-bolt fastener 450, such as with threads or a connector, such as a set screw 570.

Display modules can be used for the display of information. In some applications, such as digital billboards or scoreboards, individual display modules can be connected, such as to form a larger display surface or to a mating surface, such as for mounting one or more display modules. Display modules can have different pixel spacing that can influence display characteristics. In an example, uniform pixel spacing, e.g., substantially the same internal pixel spacing and pixel spacing between adjacent display modules, can improve overall picture quality when one or more display modules are connected to form a larger display surface.

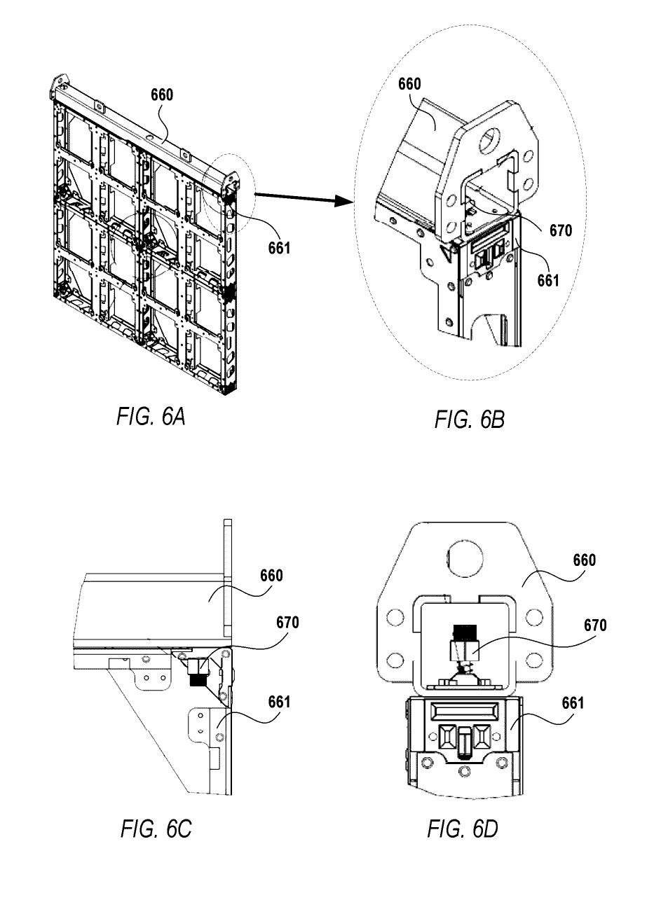

FIGS. 6A-6D show various view of an example fastening system 661 that is coupled to a corresponding mating structure. The corresponding mating structure can be on a support structure, such as a rigging beam 660 as shown in the example of FIGS. 6A-6D. The fastening system 661 can be substantially similar or identical to the fastening system 100 described above with respect to FIGS. 1A-5. For example, the fastening system 661 can include a fastener 670 that can move from an unengaged position to an engaged position, such as to create a joint between the fastening system 661 and the corresponding mating structure on the rigging beam 660.

FIG. 6C shows a side view of an example of a first fastening system 661 adjacent to a rigging beam 660. In the example shown in FIG. 6C, the fastener 670 is in an engaged position. FIG. 6D shows an end view of the fastening system 661 adjacent to a rigging beam 660. The fastener 670 can be retained in an unengaged position within the rigging beam 660. The fastener 670 can be moved to an engaged position, such as to create a joint between the fastening system 661 and the corresponding mating structure of the rigging beam 600.

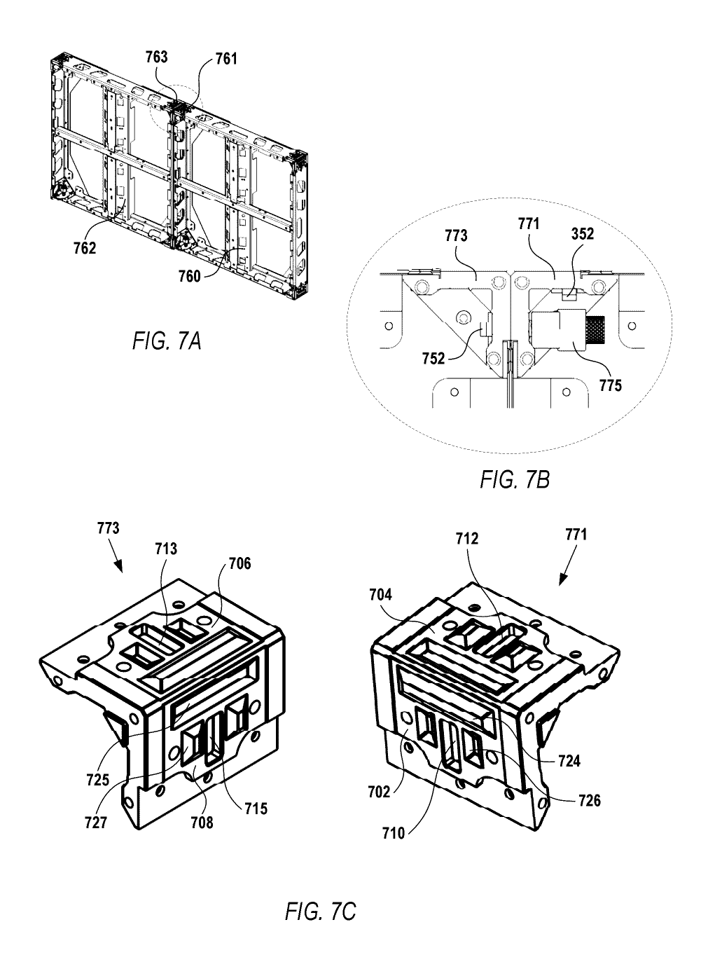

FIGS. 7A and 7B show a first example display module 760 including a first fastening system 761. The first display module 760 is positioned adjacent to a first corresponding mating structure. In the example, the first corresponding mating structure is a structure on a corresponding adjacent second display module 762. As shown in the example of FIGS. 7A and 7B, the second display module 762 can include a second fastening system 763, and the second fastening system 763 can include the first corresponding mating structure.

Each fastening system 761, 763 can be substantially similar or identical to the fastening system 100 described above with respect to FIGS. 1A-5. For example, the first fastening system 761 can include a first corner block 771 , one or more fastener stops 352 on a first retainer (not shown), and a first fastener 775. Similarly, the second fastening system 763 can include a second corner block 773, and one or more fastener stops 352 on a second retainer (not shown). The first corner block 771 can include a first block plate 702 with a first block fastener hole 710, a second block plate 704 with a first block receiver hole 712, and at least one of a first protuberance 724 extending from an exterior surface of the first corner block 771 and first cavity 726 into the first exterior surface. The second corner block 773 can include a third block plate 706 with a second block fastener hole 713, a fourth block plate 708 with a second block receiver hole 715, and at least one of a second cavity 725 into an exterior surface of the second corner block 773 corresponding to the first protuberance 724 and a second protuberance 727 extending from the second external surface corresponding to the first cavity 726.

The first display module 760 can be positioned adjacent to the second display module 762 so that the first fastening system 761 is adjacent to the second fastening system 763. This positioning of the first display module 760 can include engaging at least one of the first protuberance 724 with the second cavity 725 and the first cavity 726 with the second protuberance 727.

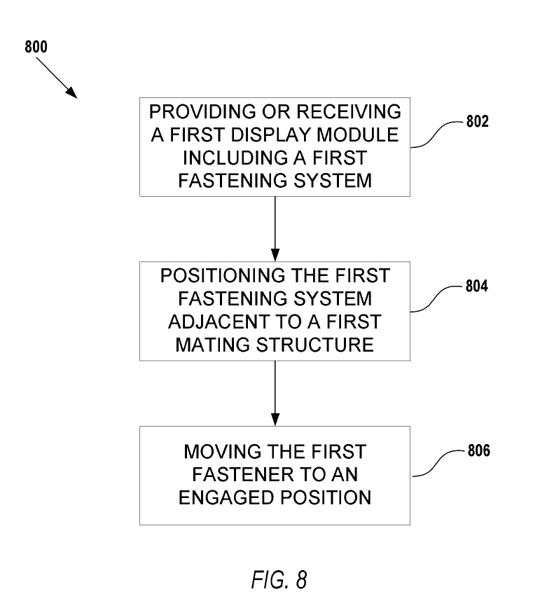

FIG. 8 is a flow diagram of an example method 800 for connecting one or more display modules to form a larger display. At 802, a first display module 760 including a first fastening system 761 can be provided or received. The first fastening system 761 can include a first corner block 771, one or more fastener stops 352 on a first retainer (not shown), and a first fastener 775. The first fastener 775 can be moved between an unengaged position and an engaged position, such as with respect to a first mating structure.

At 804, the first display module 760 can be positioned so that the first fastening system 761 is adjacent to a corresponding mating structure. Positioning the first display module 760 (804) can include aligning the block fastener hole 710 with the block receiver hole 712. Positioning the first display module 760 (804) can include at least one of engaging the first protuberance 724 with the second cavity 725 and engaging the first cavity 726 with the second protuberance 727. The corresponding mating structure can include any physical structure, such as a rigging beam 660 or a structure on a second display module 762, for example on the second fastening system 763.

At 806, the first fastener 775 can be moved to an engaged position, e.g., to engage the corresponding mating structure. The first fastener 775 can be moved from an unengaged position, such as a retained position, to an engaged position. Moving the fastener 775 to the engaged position can create a joint between the first display module 760 and the corresponding mating structure, such as the rigging beam 660 or the second display module 762. For example, a portion of the first fastener 775, such as a T-bold fastener 450 or a threaded bolt, can extend through the retainer fastener hole 336, the first block fastener hole 710, the second block receiver hole 715, and the retainer receiver hole 338, such as to engage the first mating structure.

Engaging the corresponding mating structure (806) can include twisting the first fastener 775 so that a portion of the first fastener 775 contacts the corresponding mating structure. For example, the first fastener 775, such as the T-bolt fastener 450, can be rotated about the longitudinal axis 459 such that the flange 454 contacts at least one of the block fastener stop 222 on the corner block 110 or the fastener stop 352 on the retainer 130. In another example, the first fastener 775 can be rotated about a longitudinal axis of the threaded bolt, such that the threaded bolt engages a threaded feature, such as a threaded hole or a threaded tube, on the corresponding mating structure.

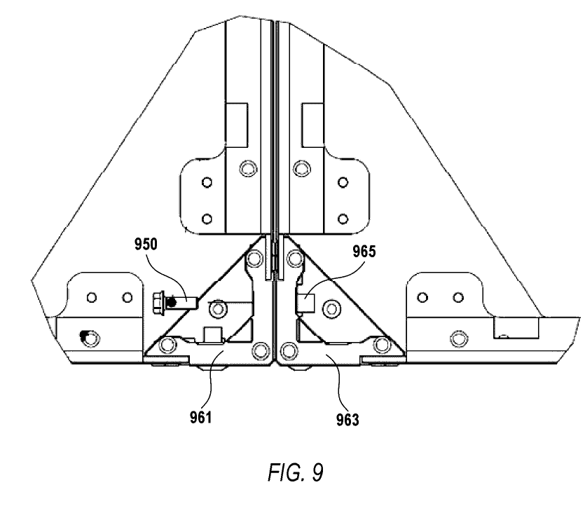

FIG. 9 shows an example of a first fastening system 961 and a second fastening system 963 connected to form a joint with a fastener 950, such as a threaded bolt. The fastener 950 can be moved from an unengaged position on the first fastening system 961 and made to contact the second fastening system 963, such as at a threaded tube 965, to achieve an engaged position.

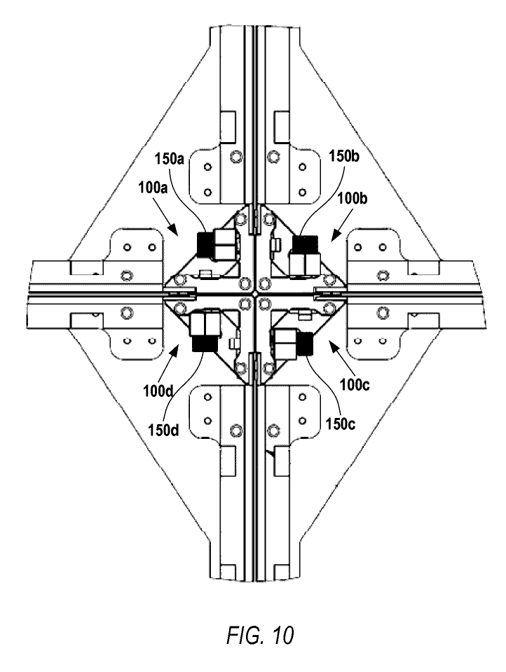

FIG. 10 shows an example of multiple fastening systems 100a, 100b, 100c, and 100d connected to form multiple joints. In the example shown in FIG. 10, a first fastening system 100a, a second fastening system 100b, a third fastening system 100c and a fourth fastening system 100d are connected to create a larger display surface. For example, the first, second, third and fourth fastening systems 100a, 100b, 100c, 100d can be connected by one or more fasteners, such as T-bolt fasteners 450a, 450b, 450c, and 450d respectively, or by threaded bolts.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A fastening system, comprising:
a corner block, comprising a first block plate and a second block plate, the first and second block plates being angled relative to one another, the corner block including a block fastener hole through the first block plate;
a retainer, comprising a first retainer plate and a second retainer plate, the first and second retainer plates being angled relative to one another, the retainer including a retainer fastener hole through the first retainer plate, wherein interior surfaces of the first and second block plates are proximate to respective exterior surfaces of the first and second retainer plates and the corner block and the retainer are aligned such that the retainer fastener hole is substantially aligned with the block fastener hole; and
a fastener retained by at least one of the corner block and the retainer proximate to or in at least one of the block fastener hole and the retainer fastener hole, the fastener being movable between an unengaged position and an engaged position,
wherein a portion of the fastener extends through the block fastener hole and the retainer fastener hole when the fastener is in the engaged position.

2. The fastening system of claim 1, wherein the corner block includes at least one of a protuberance extending from an exterior surface and a cavity into the exterior surface, wherein the at least one of the protuberance and the cavity is configured to locate the corner block with respect to a corresponding mating structure.

3. The fastening system of claim 2, wherein the at least one protuberance is a frustum with a substantially rectangular cross section and the at least one cavity is a frustum with a substantially rectangular cross section.

4. The fastening system of claim 2, wherein the corresponding mating structure is on a corresponding second fastening system.

5. The fastening system of claim 1, wherein the fastener includes a T-bolt fastener.

6. The fastening system of claim 1, further comprising a biasing structure to bias the fastener into the unengaged position.

7. The fastening system of claim 1, comprising a turn handle located on the fastener and configured to allow a user to rotate the fastener about a longitudinal axis of the fastener.

8. The fastening system of claim 1, wherein the corner block comprises a block receiver hole through the second block plate and the retainer comprises a retainer receiver hole through the second receiver plate, wherein the corner block and the retainer are aligned so that the block receiver hole is substantially aligned with the retainer receiver hole.

9. The fastening system of claim 8, comprising at least one fastener stop located close to the retainer receiver hole and configured to limit rotation of the fastener.

10. The fastening system of claim 8, wherein the retainer receiver hole comprises at least one of a threaded hole through the retainer and an internally threaded tube coupled to the retainer.

11. A method, comprising:
providing or receiving a first display module including a first fastening system coupled thereto, the first fastening system comprising,
a first corner block including a first block plate and a second block plate, the first and second block plates being angled relative to one another, the first corner block comprising a first block fastener hole through the first block plate,
a first retainer comprising a first retainer plate and a second retainer plate, the first and second retainer plates being angled relative to one another, the first retainer comprising a first retainer fastener hole through the first retainer plate, wherein interior surfaces of the first and second block plates are proximate to respective exterior surfaces of the first and second retainer plate such that the first retainer fastener hole is substantially aligned with the first block fastener hole, and
a first fastener retained by at least one of the first corner block and the first retainer proximate to or in at least one of the second block fastener hole and the second retainer fastener hole, the first fastener being movable relative to the first retainer between a first unengaged position and a first engaged position;
positioning the first display module so that the first fastening system is adjacent to a corresponding first mating structure; and
moving the first fastener to the first engaged position so that a portion of the first fastener extends through the first retainer fastener hole and the first block fastener hole to engage the corresponding first mating structure.

12. The method of claim 11, wherein the first display module comprises a first array of a plurality of first light-emitting elements configured to display visual information.

13. The method of claim 11, wherein the corresponding first mating structure is on a second display module.

14. The method of claim 13, wherein the second display module comprises a second array of a plurality of second light-emitting elements configured to display visual information, wherein the first array and the second array are configured to operate together and form a common display for the visual information.

15. The method of claim 13, wherein the second display module comprises a second fastening system and the second fastening system comprises the corresponding first mating structure, wherein positioning the first display module comprises positioning the first fastening system adjacent to the second fastening system.

16. The method of claim 15, wherein the second fastening system comprises:
a second corner block, including a third block plate and a fourth block plate, the third and fourth block plates being angled relative to one another, the second corner block comprising a second block fastener hole through the third block plate and a second block receiver hole through the fourth block plate;
a second retainer comprising a third retainer plate and a fourth retainer plate, the third and fourth retainer plates being angled relative to one another, the second retainer comprising a second retainer fastener hole through the third retainer plate and a second retainer receiver hole through the fourth retainer plate, wherein interior surfaces of the third and fourth block plates are proximate to respective exterior surfaces of the third and fourth retainer plates such that the second retainer fastener hole is substantially aligned with the second block fastener hole and the second retainer receiver hole is substantially aligned with the second block receiver hole; and
a second fastener retained by at least one of the second corner block and the second retainer proximate to or in at least one of the first block fastener hole and the first retainer fastener hole the second fastener being movable relative to the second retainer between a second unengaged position and a second engaged position.

17. The method of claim 16, wherein:
the first corner block comprises at least one of: a first protuberance extending from a first exterior surface of the first corner block; and a first cavity into the first exterior surface; and
the second corner block comprises at least one of: a second cavity into a second exterior surface of the second corner block corresponding to the first protuberance; and a second protuberance extending from the second external surface corresponding to the first cavity,
wherein positioning the first display module comprises at least one of engaging the first protuberance with the second cavity and engaging the first cavity with the second protuberance.

18. The method of claim 12, wherein moving the first fastener to the first engaged position includes advancing the first T-bolt through at least one of the second retainer receiver hole and the second block receiver hole of the second corner block and rotating the T-bolt about a longitudinal axis.

19. The method of claim 12, wherein moving the first fastener to the first engaged position includes advancing a threaded shaft of the first fastener to at least one of the second retainer receiver hole and the second block receiver hole of the second corner block wherein the second retainer receiver hole and the second block receiver hole are configured to receive the threaded shaft and rotating the threaded shaft about a longitudinal axis.

20. A fastening system for connecting display modules each comprising an array of pixels having an internal pixel spacing, the fastening system comprising:
a corner block, comprising a first block plate and a second block plate, the first and second block plates being angled relative to one another, the corner block including a block fastener hole through the first block plate and a fastener retainer hole through the second block plate;
a retainer, comprising a first retainer plate and a second retainer plate, the first and second retainer plates being angled relative to one another, the retainer including a retainer fastener hole through the first retainer plate and a fastener retainer hole through the second fastener plate; and
a fastener retained within the retainer fastener hole, the fastener being movable relative to the retainer between an unengaged position and an engaged position,
wherein interior surfaces of the first and second block plates are proximate to respective exterior surfaces of the first and second retainer plates such that the retainer receiver hole is substantially aligned with the block receiver hole and the retainer fastener hole is substantially aligned with the block fastener hole so that a portion of the fastener extends through the retainer fastener, and
wherein the fastening system maintains a pixel spacing between adjacent connected display modules that is substantially equal to the internal pixel spacing of the display modules.
